(19) United States
(12) Patent Application Publication
(10) Pub. No.: US 2025/0133791 A1
(43) Pub. Date: Apr. 24, 2025

(54) INTEGRATED CIRCUIT DEVICE

(71) Applicant: SAMSUNG ELECTRONICS CO., LTD., SUWON-SI (KR)

(72) Inventors: Chaeho Na, Suwon-si (KR); Sangkoo Kang, Suwon-si (KR); Sunki Min, Suwon-si (KR)

(21) Appl. No.: 18/741,416

(22) Filed: Jun. 12, 2024

(30) Foreign Application Priority Data
Oct. 23, 2023 (KR) 10-2023-0142337

(51) Int. Cl. H01L 29/08; H01L 27/092; H01L 29/06; H01L 29/423; H01L 29/775; H01L 29/786

(52) U.S. Cl. CPC H10D 62/151; H10D 30/43; H10D 30/6735; H10D 30/6757; H10D 62/121; H10D 84/85

(57) ABSTRACT

An integrated circuit device includes a first fin-type active region and a second fin-type active region, each extending on a substrate in a first horizontal direction, a plurality of gate lines on the first fin-type active region and second fin-type active region, the plurality of gate lines extending in a second horizontal direction that crosses the first horizontal direction, a first source/drain region and a second source/drain region respectively in the first fin-type active region and second fin-type active region, wherein each of the first source/drain region and the second source/drain region is disposed between the plurality of gate lines, a spacer structure disposed on the plurality of gate lines, the first source/drain region and the second source/drain region, and a protective insulating film disposed on the second source/drain region and exposing the first source/drain region.

### CROSS-REFERENCE TO RELATED APPLICATION

This application is based on and claims priority under 35 U.S.C. § 119 to Korean Patent Application No. 10-2023-0142337, filed on Oct. 23, 2023, in the Korean Intellectual Property Office, the disclosure of which is incorporated by reference herein in its entirety.

### BACKGROUND

### 1. Technical Field

The inventive concept relates to an integrated circuit device. More particularly, the inventive concept relates to an integrated circuit device including a field-effect transistor (FET).

### 2. Discussion of Related Art

With the rapid development and down-scaling of integrated circuit devices, the accuracy of the operations of integrated circuit devices as well as the operating speed thereof needs to be secured. That is, as an integration density of integrated circuit devices increases and the size thereof decreases, a probability of defects arising during a manufacturing process may increase.

### SUMMARY

The inventive concept provides an integrated circuit device for providing increased reliability and stable performance.

Objectives and implementations of the inventive concept are not limited to those mentioned herein, and other objectives and implementations will be clearly understood by those skilled in the art from the descriptions below.

According to an aspect of the inventive concept, there is provided an integrated circuit device including a first fin-type active region and a second fin-type active region, each extending on a substrate in a first horizontal direction, a plurality of gate lines on the first fin-type active region and the second fin-type active region, the plurality of gate lines extending in a second horizontal direction that crosses the first horizontal direction, a first source/drain region and a second source/drain region respectively in the first fin-type active region and the second fin-type active region, wherein each of the first source/drain region and the second source/drain region is disposed between the plurality of gate lines, a spacer structure disposed on the plurality of gate lines, the first source/drain region and the second source/drain region, and a protective insulating film disposed on the second source/drain region and exposing the first source/drain region.

According to another aspect of the inventive concept, there is provided an integrated circuit device including a substrate including a first device region, a second device region, and a device isolation region defining the first device region and the second device region, a first fin-type active region in the first device region and a second fin-type active region in the second device region, the first fin-type active region and the second fin-type active region extending in a first horizontal direction, a nanosheet stack disposed on each of the first fin-type active region and the second fin-type active region, a gate line disposed above the first fin-type active region and the second fin-type active region, the gate line surrounding the nanosheet stack and extending across the first second device region and the second device region and the device isolation region in a second horizontal direction that crosses the first horizontal direction, a first source/drain region in the first fin-type active region and a second source/drain region in the second fin-type active region, the first source/drain region and the second source/drain region being adjacent to the gate line and in contact with the nanosheet stack, a spacer structure covering a sidewall of the gate line and portions of the first source/drain region and the second source/drain region, an insulating liner covering the spacer structure and top surfaces of the first source/drain region and the second source/drain region, and a protective insulating film disposed only on the second source/drain region and exposing the first source/drain region.

According to a further aspect of the inventive concept, there is provided an integrated circuit device including a first fin-type active region and a second fin-type active region, a first source/drain region disposed in the first fin-type active region and a second source/drain region disposed in the second fin-type active region, a plurality of nanosheet stacks each including at least one nanosheet in contact with any one of the first fin-type active region and the second fin-type active region, a gate line disposed above the first fin-type active region and the second fin-type active region, the gate line surrounding the at least one nanosheet and extending in a direction that crosses an extension direction of the first fin-type active region and the second fin-type active region, a plurality of spacer structures covering the gate line and the first source/drain region and the second source/drain region, a protective insulating film disposed only on the second source/drain region among the first source/drain region and the second source/drain region, and an insulating liner covering a top surface of the first source/drain region, a top surface of the protective insulating film, and sidewalls of the plurality of spacer structures, wherein the protective insulating film includes a silicon nitride film, and a difference between a height of the insulating liner above the second fin-type active region and a height of the insulating liner above the first fin-type active region corresponds to a thickness of the protective insulating film.

### BRIEF DESCRIPTION OF THE DRAWINGS

Embodiments will be more clearly understood from the following detailed description taken in conjunction with the accompanying drawings in which:

FIG. 1 is a plane layout diagram of an integrated circuit device according to embodiments;

FIG. 2A is a cross-sectional view showing a partial configuration of a cross-section taken along line X1-X1′ in FIG. 1;

FIG. 2B is a cross-sectional view showing a partial configuration of a cross-section taken along line X2-X2′ in FIG. 1;

FIG. 3 is a block diagram of an integrated circuit device according to embodiments; and

FIGS. 4A to 4C, FIGS. 5A to 5C, FIGS. 6A to 6D, FIGS. 7A to 7C, FIGS. 8A and 8B, FIGS. 9A and 9B, FIGS. 10A and 10B, FIGS. 11A and 11B, FIGS. 12A and 12B, FIGS. 13A and 13B, FIGS. 14A and 14B are diagrams illustrating the manufacturing processes of an integrated circuit device, according to embodiments.

### DETAILED DESCRIPTION

Hereinafter, embodiments will be described in detail with reference to the accompanying drawings. In the drawings, like reference characters denote like elements, and redundant descriptions thereof may be omitted.

The present disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the present disclosure. In the present disclosure, certain detailed descriptions may be omitted when they serve to obscure the essence of the inventive concept.

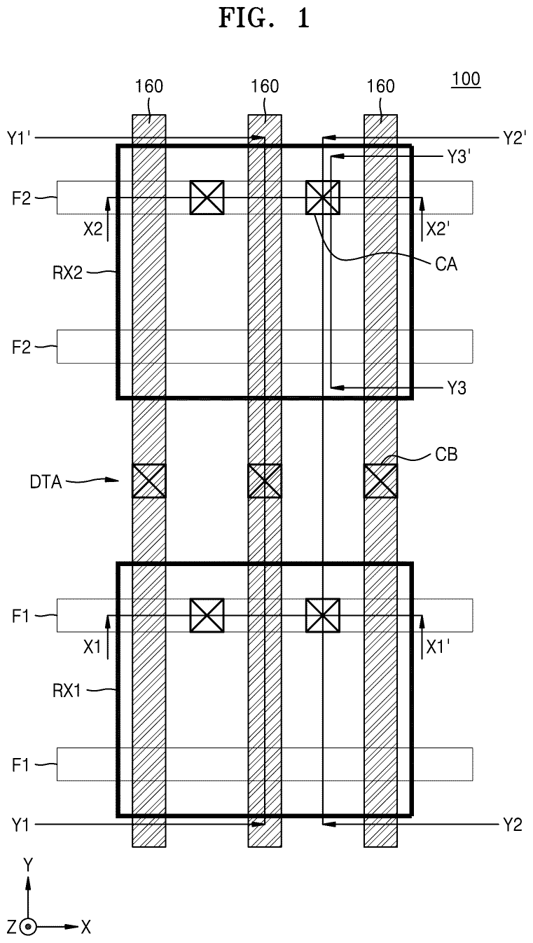

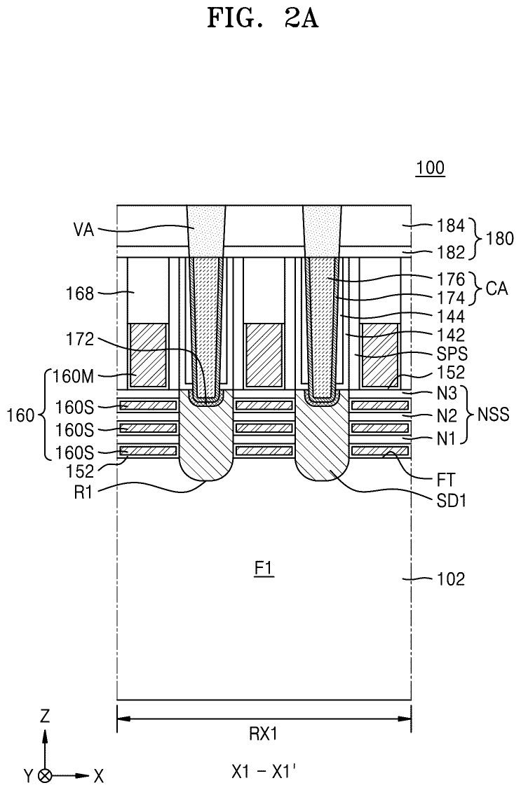

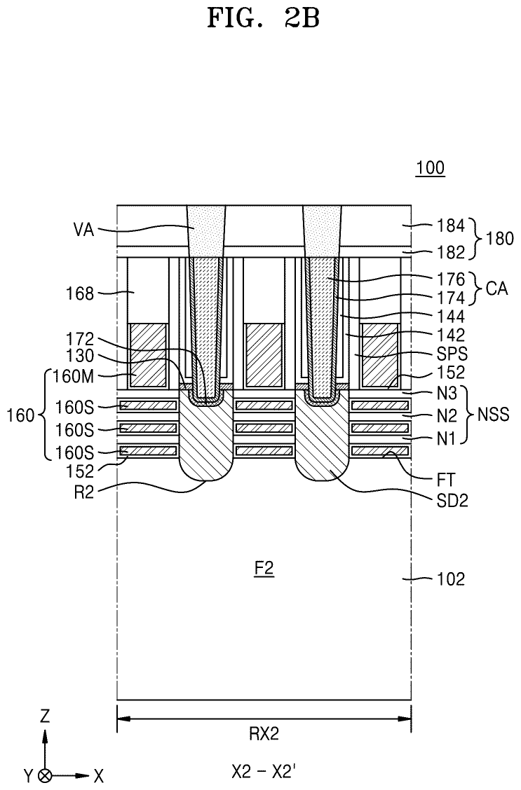

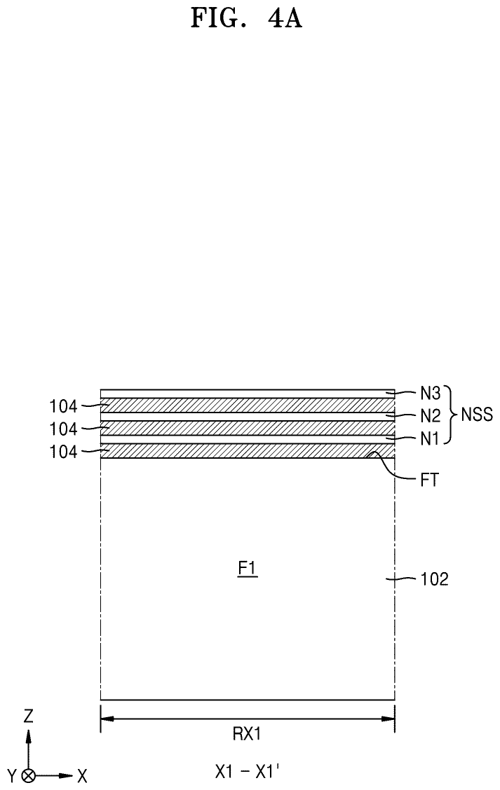

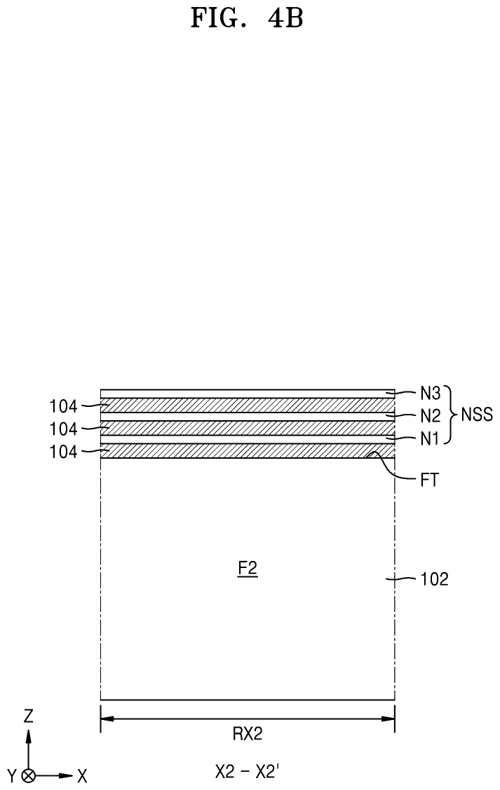

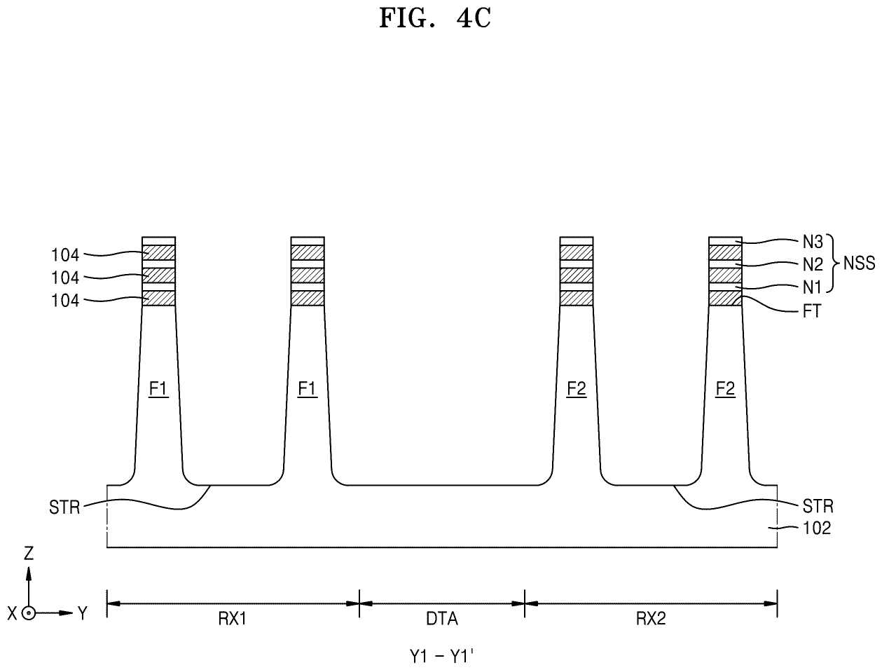

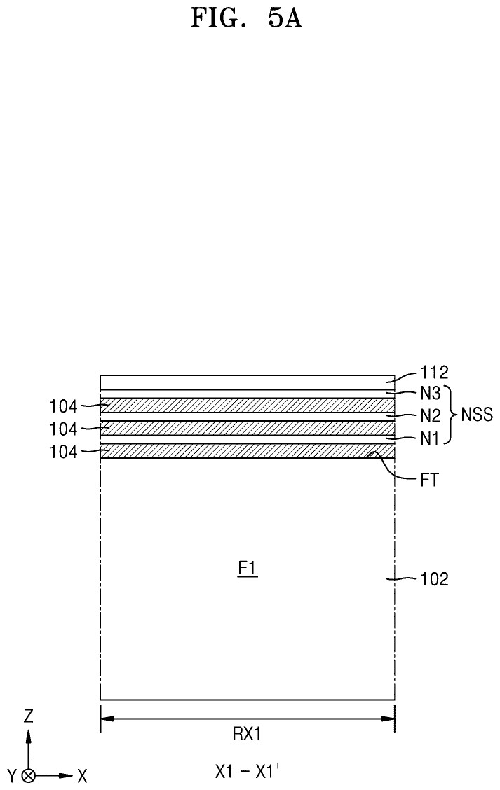

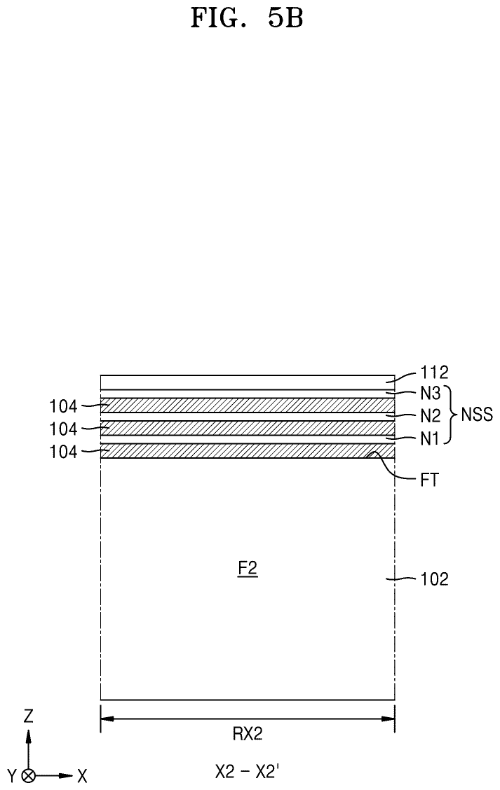

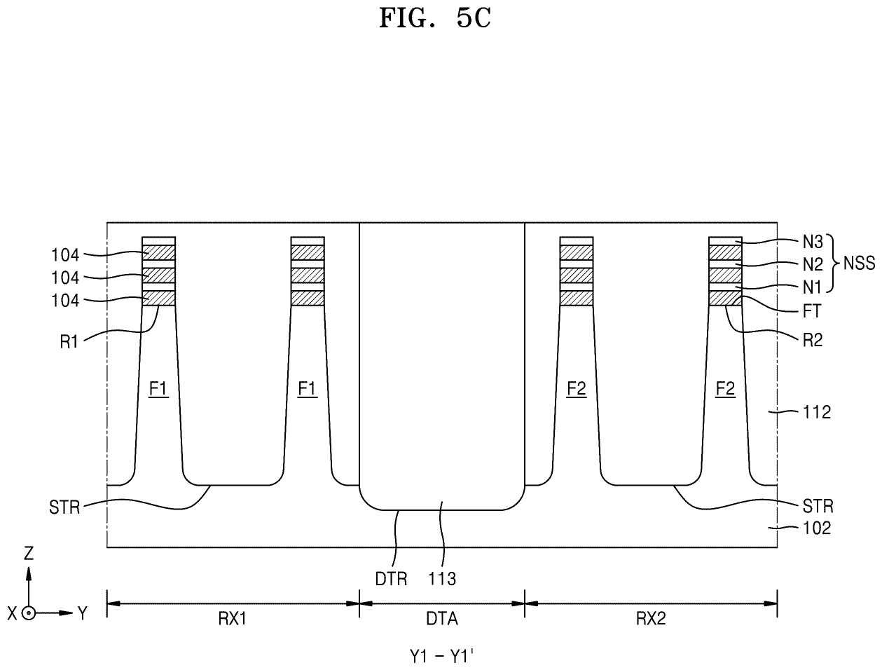

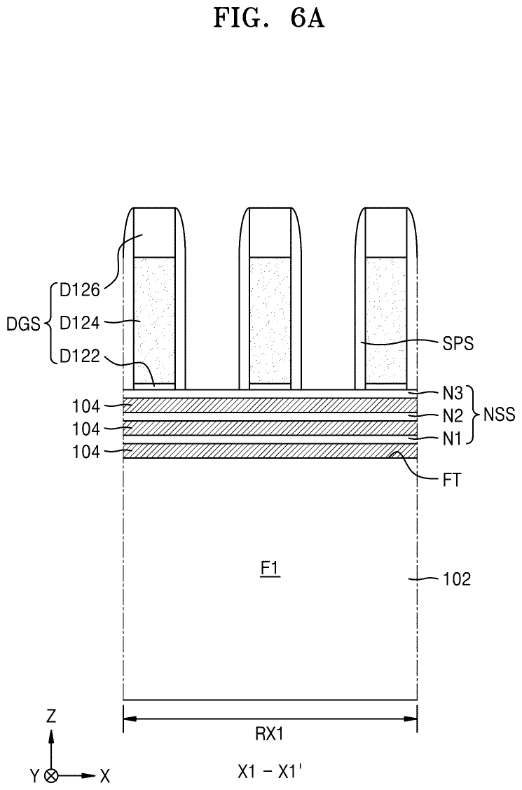

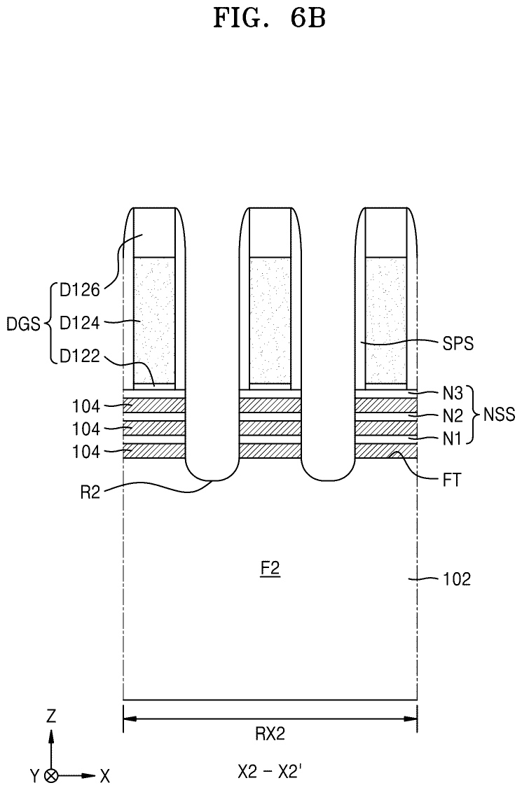

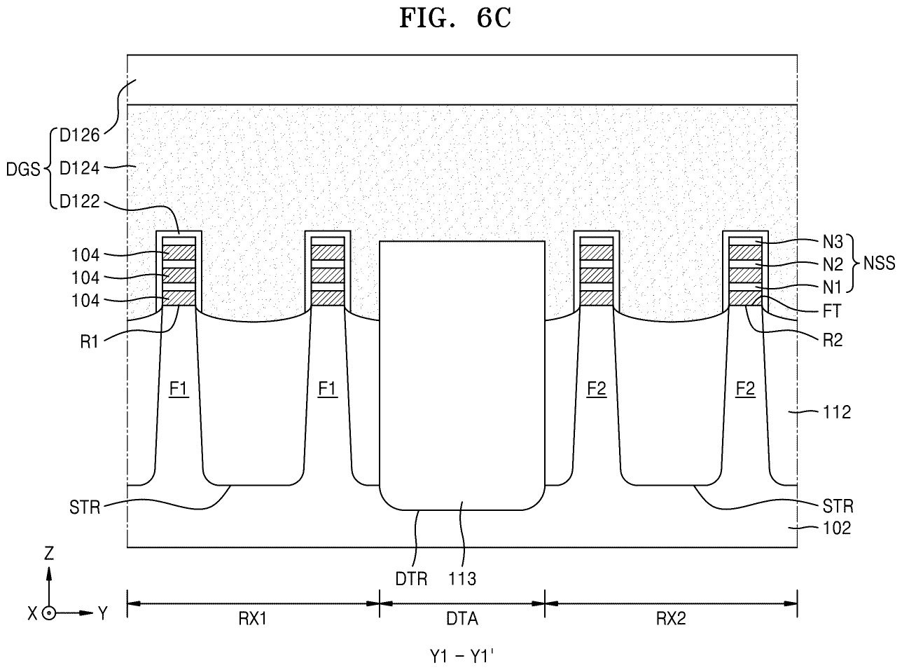

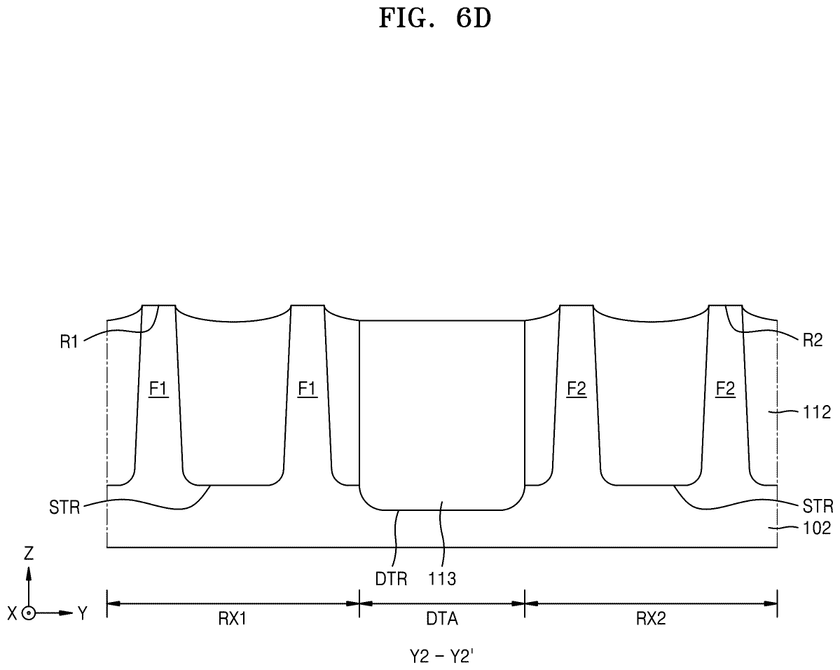

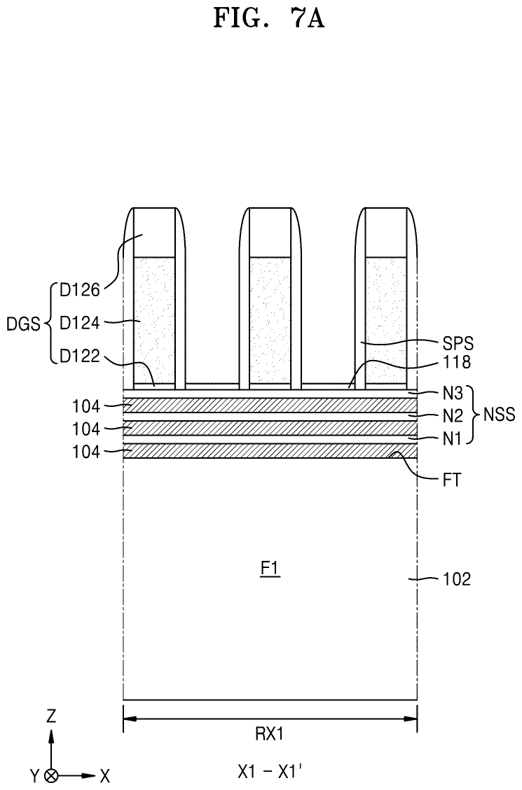

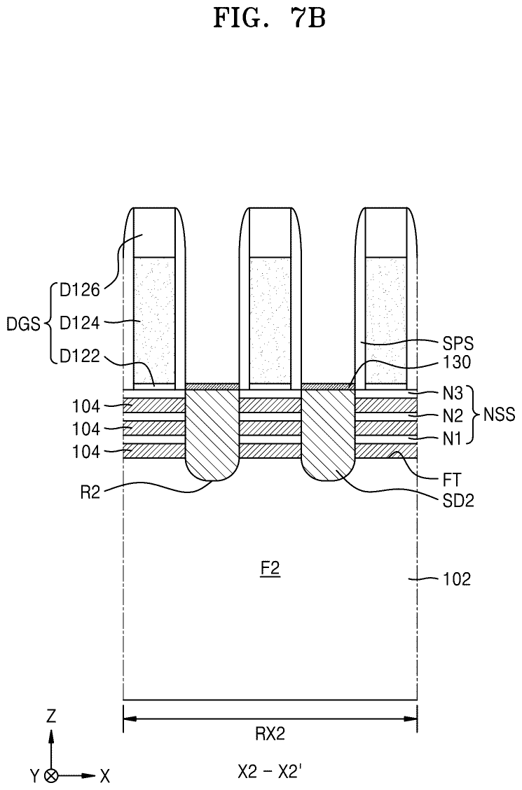

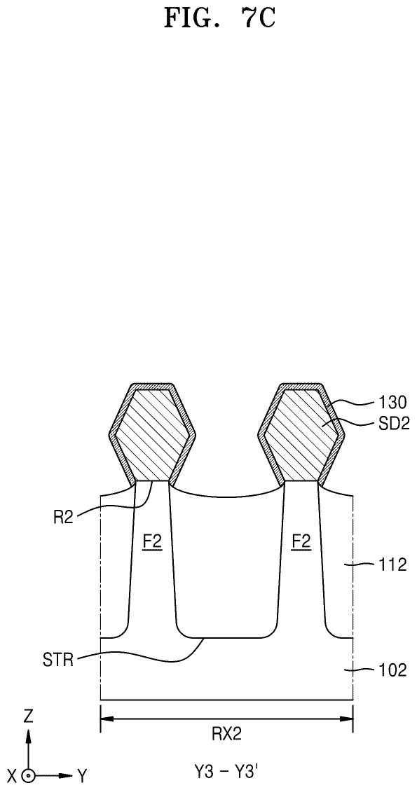

FIG. 1 is a plane layout diagram of an integrated circuit device 100 according to embodiments. FIG. 2A is a cross-sectional view showing a partial configuration of a cross-section taken along line X1-X1′ in FIG. 1. FIG. 2B is a cross-sectional view showing a partial configuration of a cross-section taken along line X2-X2′ in FIG. 1. FIG. 4C, FIG. 5C, and FIG. 6C are cross-sectional views showing a configuration of a cross-section taken along line Y1-Y1′ in some manufacturing processes of the integrated circuit device 100 of FIG. 1. FIG. 6D is a cross-sectional view showing a configuration of a cross-section taken along line Y2-Y2′ in some manufacturing processes of the integrated circuit device 100 of FIG. 1. FIG. 7C is a cross-sectional view showing a configuration of a cross-section taken along line Y3-Y3′ in some manufacturing processes of the integrated circuit device 100 of FIG. 1.

Referring to these drawings, the integrated circuit device 100 may include a substrate 102, which includes a first device region RX1, a second device region RX2, and a device isolation region DTA between the first device region RX1 and the second device region RX2. A deep trench DTR may be formed in the substrate 102 in the device isolation region DTA. The first device region RX1 and the second device region RX2 may be at least partially defined by the deep trench DTR.

The substrate 102 may include a semiconductor, such as silicon (Si) or germanium (Ge), or a compound semiconductor, such as SiGe, SiC, GaAs, InAs, InGaAs, or InP. Each of the terms “SiGe”, “SiC”, “GaAs”, “InAs”, “InGaAs”, and “InP” used herein indicates a material composed of elements included in each term and may not be a chemical equation representing stoichiometric relationships. The substrate 102 may include a conductive region, e.g., an impurity-doped well or an impurity-doped structure.

A plurality of trench regions may be defined by a plurality of fin-type active regions (e.g., F1) in the substrate 102. A first buried insulating film 112 may be disposed in the trench regions. The first buried insulating film 112 may cover at least a portion of a sidewall of each of the fin-type active regions (e.g., F1). The first buried insulating film 112 may correspond to an isolation film. The first buried insulating film 112 may include a silicon oxide film but is not limited thereto.

A plurality of fin-type active regions may protrude from the substrate 102 in the vertical direction (the Z direction). For example, a plurality of first fin-type active regions F1 may protrude from the substrate 102 in the vertical direction in the first device region RX1 and a plurality of second fin-type active regions F2 may protrude from the substrate 102 in the vertical direction the second device region RX2. The fin-type active regions (e.g., F1 and F2) may extend in a first horizontal direction (the X direction) and be substantially parallel with each other. Each of the fin-type active regions (e.g., F1 and F2) may be defined in the first device region RX1 or the second device region RX2 by an isolation trench STR formed in the substrate 102.

The fin-type active regions may include the plurality of first fin-type active regions F1 disposed in the first device region RX1 and the plurality of second fin-type active regions F2 disposed in the second device region RX2. Each of the first and second fin-type active regions F1 and F2 may have a fin top FT at a first level. The term “level” used herein may refer to a height from a top surface of the substrate 102 in the vertical direction (the Z direction or the Z direction). Although it is illustrated in FIG. 1 that two first fin-type active regions F1 are arranged in the first device region RX1 and two second fin-type active regions F2 are arranged in the second device region RX2, one fin-type active region or at least three fin-type active regions may be disposed in each of the first device region RX1 and the second device region RX2.

A gate line 160 may be disposed on the top surface of the substrate 102. The gate line 160 may extend across the first and second fin-type active regions F1 and F2 in a second horizontal direction (the Y direction) that crosses the first horizontal direction (the X direction). For example, the gate line 160 may extend across an extension direction of the first and second fin-type active regions F1 and F2. Although it is illustrated in FIG. 1 that three gate lines 160 are arranged on the first and second fin-type active regions F1 and F2, the number of gate lines 160 on the first and second fin-type active regions F1 and F2 is not particularly limited. For example, a plurality of gate lines 160 may be disposed on each of the first and second fin-type active regions F1 and F2.

The first buried insulating film 112 may be disposed in the isolation trench STR in each of the first device region RX1 and the second device region RX2. The first buried insulating film 112 may fill the isolation trench STR. The first buried insulating film 112 may be disposed between the substrate 102 and the gate line 160 and may cover the sidewall of each of the first and second fin-type active regions F1 and F2.

In the device isolation region DTA, a second buried insulating film 113 may be disposed between the substrate 102 and the gate line 160. The second buried insulating film 113 may be disposed in the deep trench DTR. For example, the second buried insulating film 113 may fill the deep trench DTR. The second buried insulating film 113 may be spaced apart from the first and second fin-type active regions F1 and F2 in the second horizontal direction (the Y direction).

The gate line 160 may extend long in the second horizontal direction (the Y direction) above the first and second fin-type active regions F1 and F2, the first buried insulating film 112, and the second buried insulating film 113. Each of a plurality of nanosheet stacks NSS may be on the fin top FT of one of the first and second fin-type active regions F1 and F2 at an intersection between a corresponding one of the first and second fin-type active regions F1 and F2 and the gate line 160. Each of the nanosheet stacks NSS may face the fin top FT of a corresponding one of the first and second fin-type active regions F1 and F2 at a position separated in the vertical direction (the Z direction) from the corresponding one of the first and second fin-type active regions F1 and F2.

Each of the nanosheet stacks NSS may include a plurality of nanosheets, which overlap each other above the fin top FT of a corresponding one of the first and second fin-type active regions F1 and F2 in the vertical direction (the Z direction). The term “nanosheet” used herein refers to a conductive structure having a cross-section that is substantially perpendicular to a direction in which electric current flows. It will be understood that the nanosheet includes a nanowire. The nanosheets may respectively have different vertical distances (Z-direction distances) from the fin top FT. The nanosheets may include a first nanosheet N1, a second nanosheet N2, and a third nanosheet N3, which are sequentially stacked above the fin top FT of each of the first and second fin-type active regions F1 and F2.

The numbers of nanosheet stacks NSS and gate lines 160, which are arranged above one fin-type active region, e.g., the first fin-type active region F1 or the second fin-type active region F2, are not particularly limited. For example, one or more nanosheet stacks NSS and one or more gate lines 160 may be disposed above one fin-type active region, e.g., the first fin-type active region F1 or the second fin-type active region F2.

Although FIG. 2A and FIG. 2B illustrate the case where each of the nanosheet stacks NSS includes three nanosheets, i.e., a first nanosheet N1, a second nanosheet N2, and a third nanosheet N3, embodiments are not limited thereto. The number of nanosheets included in each nanosheet stack NSS is not particularly limited. For example, each of the nanosheet stacks NSS may include one nanosheet, two nanosheets, or at least four nanosheets. Each of the first, second, and third nanosheets N1, N2, and N3 may have a channel region. For example, each of the first, second, and third nanosheets N1, N2, and N3 may have a thickness selected from a range from about 4 nanometers (nm) to about 6 nm. At this time, the thickness of each of the first, second, and third nanosheets N1, N2, and N3 refers to a size in the vertical direction (the Z direction). In embodiments, the first, second, and third nanosheets N1, N2, and N3 may have substantially the same thickness as one another in the vertical direction (the Z direction). In some embodiments, at least some of the first, second, or third nanosheets N1, N2, and N3 may have different thicknesses from each other in the vertical direction (the Z direction).

As shown in FIG. 2A and FIG. 2B, the first, second, and third nanosheets N1, N2, and N3 of one nanosheet stack NSS may have the same size as one another in the first horizontal direction (the X direction). In some embodiments, at least some of the first, second, or third nanosheets N1, N2, and N3 of one nanosheet stack NSS may have different sizes from each other in the first horizontal direction (the X direction). For example, the length of each of the first and second nanosheets N1 and N2, which are relatively close to the fin top FT, may be less than the length of the third nanosheet N3, which is farthest from the fin top FT, in the first horizontal direction (the X direction).

As shown in FIG. 2A, a plurality of first recesses R1 may be formed in the top surface of the first fin-type active region F1 in the first device region RX1. As shown in FIG. 2B, a plurality of second recesses R2 may be formed in the top surface of the second fin-type active region F2 in the second device region RX2. Although FIG. 2A and FIG. 2B illustrate the case where the level of the bottommost surface of each of the first recesses R1 and the second recesses R2 is lower than the level of the fin top FT of each of the first and second fin-type active regions F1 and F2, embodiments are not limited thereto. The level of the bottommost surface of each of the first recesses R1 and the second recesses R2 may be the same as or similar to the level of the fin top FT of each of the first and second fin-type active regions F1 and F2.

As shown in FIG. 2A and FIG. 2B, a plurality of first source/drain regions SD1 may be formed on the first recesses R1 in the first device region RX1, and a plurality of second source/drain regions SD2 may be formed on the second recesses R2 in the second device region RX2.

The gate line 160 may be on the first and second fin-type active regions F1 and F2 to cover the nanosheet stacks NSS and surround each of the first, second, and third nanosheets N1, N2, and N3. A plurality of transistors may be formed above the substrate 102 at intersections between the first and second fin-type active regions F1 and F2 and the gate line 160. In embodiments, the first device region RX1 may correspond to an N-channel metal-oxide semiconductor (NMOS) transistor region and the second device region RX2 may correspond to a P-channel MOS (PMOS) transistor region. NMOS transistors may be respectively formed at the intersections between the first fin-type active regions F1 and the gate line 160 in the first device region RX1. PMOS transistors may be respectively formed at the intersections between the second fin-type active regions F2 and the gate line 160 in the second device region RX2.

The gate line 160 may include a main gate portion 160M and a plurality of sub gate portions 160S. The main gate portion 160M may extend long in the second horizontal direction (the Y direction) to cover the top surface of a nanosheet stack NSS. The sub gate portions 160S may be integrally connected to the main gate portion 160M and respectively between the third nanosheet N3 and the second nanosheet N2, between the second nanosheet N2 and the first nanosheet N1, and between the first nanosheet N1 and the first or second fin-type active region F1 or F2.

The gate line 160 may include metal, metal nitride, metal carbide, or a combination thereof. The metal may be, for example, Ti, W, Ru, Nb, Mo, Hf, Ni, Co, Pt, Yb, Tb, Dy, Er, or Pd. The metal nitride may be, for example, TiN or TaN. The metal carbide may include, for example, TiAlC. However, the material of the gate line 160 is not limited to those mentioned herein.

A gate dielectric film 152 may be disposed between the first, second, and third nanosheets N1, N2, and N3 and the gate line 160. In embodiments, the gate dielectric film 152 may include a stack structure of an interface dielectric film and a high-k dielectric film. The interface dielectric film may include a low-k dielectric film, e.g., a silicon oxide film, a silicon oxynitride film, or a combination thereof, having a permittivity of about 9 or less. In embodiments, the interface dielectric film may be omitted. The high-k dielectric film may include a material having a higher dielectric constant than a silicon oxide film. For example, the high-k dielectric film may have a dielectric constant of about 10 to about 25. The high-k dielectric film may include hafnium oxide but is not limited thereto.

The gate dielectric film 152 may include portions covering the surfaces of the first, second, and third nanosheets N1, N2, and N3; portions covering the sidewalls of the main gate portion 160M; a portion covering the fin top FT of each of the first and second fin-type active regions F1 and F2, a portion covering the top surface of the first buried insulating film 112, and a portion covering the top surface of the second buried insulating film 113.

The first, second, and third nanosheets N1, N2, and N3 may respectively include semiconductor layers including the same element. For example, each of the first, second, and third nanosheets N1, N2, and N3 may include an Si layer. In the first device region RX1, the first, second, and third nanosheets N1, N2, and N3 may be doped with a dopant of the same conductivity type as the first source/drain regions SD1. In the second device region RX2, the first, second, and third nanosheets N1, N2, and N3 may be doped with a dopant of the same conductivity type as the second source/drain regions SD2. For example, the first, second, and third nanosheets N1, N2, and N3 in the first device region RX1 may include an Si layer doped with an n-type dopant, and the first, second, and third nanosheets N1, N2, and N3 in the second device region RX2 may include an Si layer doped with a p-type dopant.

Both sidewalls of the gate line 160 above the first and second fin-type active regions F1 and F2 may be covered with an insulating spacer structure SPS (see FIG. 2A and FIG. 2B). The insulating spacer structure SPS may be above the top surface of the nanosheet stacks NSS to cover both sidewalls of the main gate portion 160M. The insulating spacer structure SPS may be separated from the gate line 160 by the gate dielectric film 152. The insulating spacer structure SPS may include silicon nitride, silicon oxide, SiCN, SiBN, SiON, SiOCN, SiBCN, SiOC, or a combination thereof. Each of the terms “SiCN”, “SiBN”, “SiON”, “SiOCN”, “SiBCN”, and “SiOC” used herein indicates a material composed of elements included in each term and may not be a chemical equation representing stoichiometric relationships.

As shown in FIG. 2B, each of both sidewalls of each of the sub gate portions 160S in the first device region RX1 may be spaced apart from one of the second source/drain regions SD2 in the first horizontal direction (the X direction) with the gate dielectric film 152 between the sidewall of each sub gate portion 160S and the second source/drain region SD2. In the second device region RX2, the gate dielectric film 152 may include a portion in contact with the second source/drain region SD2. In the first horizontal direction (the X direction), the second source/drain region SD2 may face the nanosheet stacks NSS and the sub gate portions 160S.

In the first device region RX1, the main gate portion 160M of the gate line 160 may be separated from a first source/drain region SD1 by the insulating spacer structure SPS. In the second device region RX2, the main gate portion 160M of the gate line 160 may be separated from the second source/drain region SD2 by the insulating spacer structure SPS.

When the first device region RX1 is an NMOS transistor region and the second device region RX2 is a PMOS transistor region, the first source/drain regions SD1 in the first device region RX1 may include an Si or SiC layer doped with an n-type dopant and the second source/drain regions SD2 in the second device region RX2 may include an SiGe layer doped with a p-type dopant. The n-type dopant may be selected from among phosphorus (P), arsenic (As), and antimony (Sb). The p-type dopant may be selected from boron (B) and gallium (Ga).

The first source/drain regions SD1 in the first device region RX1 may have different shapes and sizes than the second source/drain regions SD2 in the second device region RX2. However, the inventive concept is not limited thereto. The first source/drain regions SD1 and the second source/drain regions SD2 may have various shapes and sizes in the first device region RX1 and the second device region RX2.

As shown in FIG. 2A and FIG. 2B, the top surface of each of the first and second source/drain regions SD1 and SD2 and the sidewall of the insulating spacer structure SPS may be covered with an insulating liner 142. The insulating liner 142 may conformally cover the surface of each of the first and second source/drain regions SD1 and SD2 and the insulating spacer structure SPS. The insulating liner 142 may include SiN, SiCN, SiBN, SION, SiOCN, SiBCN, SiOC, or SiO₂, or a combination thereof. At this time, in the second device region RX2 in FIG. 2B, a protective insulating film 130 may be disposed between the insulating liner 142 and each of the second source/drain regions SD2.

The protective insulating film 130 may be selectively deposited on each of the second source/drain regions SD2 in the second device region RX2. In embodiments, the protective insulating film 130 may include SiN. In embodiments, the protective insulating film 130 may be formed as a single conformal layer. In embodiments, the protective insulating film 130 may be deposited to a thickness of about 1 nm to about 3 nm.

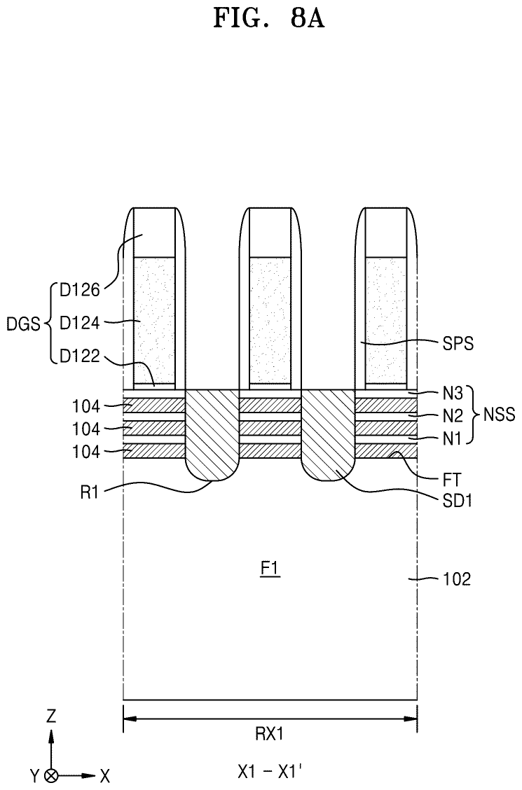

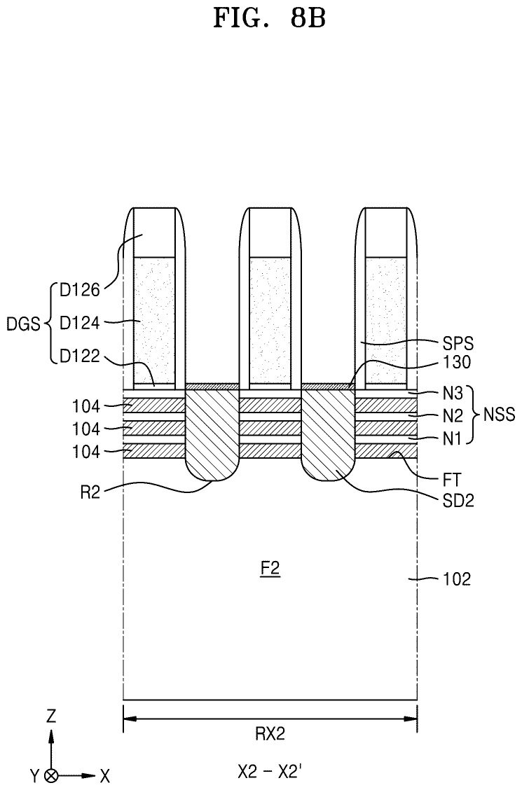

The protective insulating film 130 may be selectively deposited on each of the second source/drain regions SD2. The protective insulating film 130 may protect each second source/drain region SD2 in the second device region RX2 during a process of forming the first source/drain regions SD1 in the first device region RX1 (see FIG. 8A). An oxide film 118 may be formed in each of the first source/drain regions SD1, and when the second source/drain regions SD2 are formed (see FIG. 7B) prior to the first source/drain regions SD1 (see FIG. 7A) and the protective insulating film 130 is selectively deposited on the exposed top surface of each of the second source/drain regions SD2, open defects may be prevented from occurring in the second source/drain regions SD2 during the process (see FIG. 8A) of forming the first source/drain regions SD1.

As shown in FIG. 1, FIG. 2A, and FIG. 2B, a plurality of source/drain contacts CA may be respectively disposed on the first and second source/drain regions SD1 and SD1. Each of the source/drain contacts CA may penetrate an intergate insulating film 144, the insulating liner 142, and any one of the first and second source/drain regions SD1 and SD2 in the vertical direction (the Z direction) to be in contact with a metal silicide film 172. Each of the source/drain contacts CA may be configured to be electrically connectable to any one of the first and second source/drain regions SD1 and SD2 through the metal silicide film 172. Each of the source/drain contacts CA may be spaced apart from the main gate portion 160M with the insulating spacer structure SPS between each source/drain contact CA and the main gate portion 160M in the first horizontal direction (the X direction).

The metal silicide film 172 may be disposed between any one of the first and second source/drain regions SD1 and SD2 and the source/drain contact CA. In embodiments, the metal silicide film 172 may include Ti, W, Ru, Nb, Mo, Hf, Ni, Co, Pt, Yb, Tb, Dy, Er, or Pd. For example, the metal silicide film 172 may include titanium silicide.

The source/drain contact CA may include a conductive barrier pattern 174 and a contact plug 176, which are sequentially stacked on any one of the first and second source/drain regions SD1 and SD2. The conductive barrier pattern 174 may be in contact with and surround the bottom surface and the sidewall of the contact plug 176. Each of the source/drain contacts CA may extend long in the vertical direction (the Z direction) and penetrate the intergate insulating film 144, the insulating liner 142, and any one of the first and second source/drain regions SD1 and SD2. The conductive barrier pattern 174 may be disposed between the metal silicide film 172 and the contact plug 176. The conductive barrier pattern 174 may have a surface in contact with the metal silicide film 172 and a surface in contact with the contact plug 176. In embodiments, the conductive barrier pattern 174 may include metal or conductive metal nitride. For example, the conductive barrier pattern 174 may include Ti, Ta, W, TiN, TaN, WN, WCN, TiSiN, TaSiN, or WSiN, or a combination thereof but is not limited thereto. The contact plug 176 may include molybdenum (Mo), copper (Cu), tungsten (W), cobalt (Co), ruthenium (Ru), manganese (Mn), titanium (Ti), tantalum (Ta), or aluminum (Al), a combination thereof, or an alloy thereof but is not limited thereto.

As shown in FIG. 2A and FIG. 2B, the top surfaces of the source/drain contacts CA, a plurality of capping insulating patterns 168, and the intergate insulating film 144 may be covered with an upper insulating structure 180. The upper insulating structure 180 may include an etch stop film 182 and an interlayer insulating film 184, which are sequentially stacked on the source/drain contacts CA, the capping insulating patterns 168, and the intergate insulating film 144. The etch stop film 182 may include silicon carbide (SiC), SiN, nitrogen-doped silicon carbide (SiC: N), SiOC, AlN, AlON, AlO, or AlOC, or a combination thereof. The interlayer insulating film 184 may include an oxide film, a nitride film, an ultra low-k (ULK) film having an ultra low dielectric constant K of about 2.2 to about 2.4, or a combination thereof. For example, the interlayer insulating film 184 may include, a tetraethylorthosilicate (TEOS) film, a high density plasma (HDP) oxide film, a boro-phospho-silicate glass (BPSG) film, a flowable chemical vapor deposition (FCVD) oxide film, a SiON film, a SiN film, a SiOC film, or a SiCOH film, or a combination thereof but is not limited thereto.

As shown in FIG. 2A and FIG. 2B, a plurality of source/drain via contacts VA may be respectively disposed on the source/drain contacts CA. Each of the source/drain via contacts VA may penetrate the upper insulating structure 180 and be in contact with one of the source/drain contacts CA. Each of the first and second source/drain regions SD1 and SD2 may be configured to be electrically connected to one of the source/drain via contacts VA through the metal silicide film 172 and one of the source/drain contacts CA. The bottom surface of each of the source/drain via contacts VA may be in contact with the top surface of one of the source/drain contacts CA. Each of the source/drain via contacts VA may include a contact plug including molybdenum (Mo), copper (Cu), tungsten (W), cobalt (Co), ruthenium (Ru), manganese (Mn), titanium (Ti), tantalum (Ta), or aluminum (Al), a combination thereof, or an alloy thereof. Each of the source/drain via contacts VA may further include a conductive barrier pattern surrounding the contact plug. The conductive barrier pattern may include metal or metal nitride. For example, the conductive barrier pattern may include Ti, Ta, W, TiN, TaN, WN, WCN, TiSiN, TaSiN, or WSiN, or a combination thereof but is not limited thereto.

As shown in FIG. 1, a gate contact CB may be disposed on the gate line 160. The gate contact CB may be configured to penetrate the upper insulating structure 180 and one of the capping insulating patterns 168 in the vertical direction (the Z direction) to be connected to the gate line 160. The bottom surface of the gate contact CB may be in contact with the top surface of the gate line 160. In embodiments, the gate contact CB may include a conductive barrier pattern (not shown) and a contact plug (not shown). The detailed configuration of the conductive barrier pattern and the contact plug is substantially the same as that of the conductive barrier pattern 174 and the contact plug 176.

With respect to a first source/drain region SD1 adjacent to the gate line 160 in the first device region RX1 and a second source/drain region SD2 adjacent to the gate line 160 in the second device region RX2 in the integrated circuit device 100 of FIG. 1, FIG. 2A and FIG. 2B, when the first source/drain region SD1 is formed after the second source/drain region SD2 is formed and the protective insulating film 130 may be selectively deposited on the exposed top surface of the second source/drain region SD2, a spacer disposed on the insulating spacer structure SPS on the sidewall of the gate line 160 may be omitted, and a space for forming a first recess R1 in the first device region RX1 may be secured. Accordingly, an X-direction space margin corresponding to the thickness of an additional spacer may be secured and an open defect of the first recess R1 may be improved.

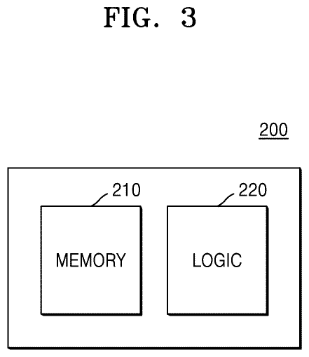

FIG. 3 is a block diagram of an integrated circuit device 200 according to embodiments.

Referring to FIG. 3, the integrated circuit device 200 may include a memory area 210 and a logic area 220. At least one of the memory area 210 and the logic area 220 may include the configuration described for the integrated circuit device 100 with reference to FIG. 1, FIG. 2A and FIG. 2B.

The memory area 210 may include at least of static random access memory (SRAM), dynamic RAM (DRAM), magnetoresistive RAM (MRAM), resistive RAM (RRAM), or phase-change RAM (PRAM). For example, the memory area 210 may include SRAM. The logic area 220 may include a standard cell, such as a counter or a buffer, which performs a desired logical function. The standard cell may include various kinds of logic cells including circuit elements, such as a transistor and a register. For example, the logic cell may constitute an AND gate, a NAND gate, an OR gate, a NOR gate, an exclusive OR (XOR) gate, an exclusive NOR (XNOR) gate, an inverter (INV), an adder (ADD), a buffer (BUF), a delay (DLY), a filter (FIL), a multiplexer (MXT/MXIT), an OR/AND/inverter (OAI) gate, an AND/OR (AO) gate, an AND/OR/inverter (AOI) gate, a D flip-flop, a reset flip-flop, a master-slave flip-flop, or a latch.

FIGS. 4A to 14B are cross-sectional views of sequential stages in a method of manufacturing an integrated circuit device, according to embodiments, wherein FIGS. 4A, 5A, . . . , and 14A show a partial configuration of a portion corresponding to the cross-section taken along line X1-X1′ in FIG. 1, FIGS. 4B, 5B, . . . , and 14B show a partial configuration of a portion corresponding to the cross-section taken along line X2-X2′ in FIG. 1, FIG. 4C, FIG. 5C, and FIG. 6C show a partial configuration of a portion corresponding to the cross-section taken along line Y1-Y1′ in FIG. 1, FIG. 6D shows a partial configuration of a portion corresponding to the cross-section taken along line Y2-Y2′ in FIG. 1, and FIG. 7C shows a partial configuration of a portion corresponding to the cross-section taken along line Y3-Y3′ in FIG. 1. In the drawings, like reference numerals denote like elements, and redundant detailed descriptions thereof may be omitted.

Referring to FIGS. 4A to 4C, a plurality of sacrificial semiconductor layers 104 and a plurality of nanosheet semiconductor layers (e.g., the first to third nanosheets N1, N2, and N3) may be alternately stacked on the substrate 102 in the first and second device regions RX1 and RX2. An isolation trench STR may be formed by partially etching each of the sacrificial semiconductor layers 104, the nanosheet semiconductor layers (e.g., the first to third nanosheets N1, N2, and N3), and the substrate 102. As a result, a plurality of first and second fin-type active regions F1 and F2, which protrude upwards from the substrate 102 in the vertical direction (the Z direction) in the first and second device regions RX1 and RX2, respectively, may be formed. A stack structure of the sacrificial semiconductor layers 104 and the nanosheet semiconductor layers (e.g., the first to third nanosheets N1, N2, and N3) may remain on the fin top FT of each of the first and second fin-type active regions F1 and F2.

The sacrificial semiconductor layers 104 may include a semiconductor material having a different etch selectivity than a semiconductor material of the nanosheet semiconductor layers (e.g., the first to third nanosheets N1, N2, and N3). In embodiments, the nanosheet semiconductor layers (e.g., the first to third nanosheets N1, N2, and N3) may include an Si layer, and the sacrificial semiconductor layers 104 may include an SiGe layer. In embodiments, the sacrificial semiconductor layers 104 may have a constant Ge content. The Ge content of the SiGe layer of the sacrificial semiconductor layers 104 may be variously changed when necessary.

Referring to FIGS. 5A to 5C, the first buried insulating film 112 may be formed on the resultant structure of FIGS. 4A to 4C and partially etched in the device isolation region DTA. A portion of the substrate 102, which may be exposed as a result of partially etching the first buried insulating film 112, may be etched, thereby forming the deep trench DTR defining the first device region RX1 and the second device region RX2. The second buried insulating film 113 may be disposed in the deep trench DTR. For example, the deep trench DTR may be filled with the second buried insulating film 113.

Referring to FIGS. 6A to 6D, a plurality of dummy gate structures DGS may be formed on the stack structure of the sacrificial semiconductor layers 104 and the nanosheet semiconductor layers (e.g., the first to third nanosheets N1, N2, and N3). Each of the dummy gate structures DGS may be formed to extend long in the second horizontal direction (the Y direction). Each of the dummy gate structures DGS may have a structure in which an oxide film D122, a dummy gate layer D124, and a capping layer D126 are sequentially stacked. In embodiments, the dummy gate layer D124 may include polysilicon and the capping layer D126 may include a silicon nitride film.

A spacer insulating film may be formed to cover opposite sidewalls of each of the dummy gate structures DGS and then anisotropically wet etched, thereby forming a plurality of insulating spacer structures SPS. A portion of each of the sacrificial semiconductor layers 104 and the nanosheet semiconductor layers (e.g., the first to third nanosheets N1, N2, and N3) and a portion of each of the second fin-type active regions F2 may be etched by using the dummy gate structures DGS and the spacer insulating film as an etch mask such that the nanosheet semiconductor layers (e.g., the first to third nanosheets N1, N2, and N3) are divided into a plurality of nanosheet stacks NSS and a second recess R2 is formed in an upper portion of each of the second fin-type active regions F2 in the second device region RX2. To form a plurality of second recesses R2, dry etching, wet etching, or a combination thereof may be used. As a result, an insulating spacer structure SPS may be obtained from the spacer insulating film. Each of the nanosheet stacks NSS may include the first nanosheet N1, the second nanosheet N2, and the third nanosheet N3.

Referring to FIG. 7A and FIG. 7B, a plurality of second source/drain regions SD2 respectively disposed in the second recesses R2 may be formed in the resultant structure of FIGS. 6A to 6D.

The second source/drain regions SD2 may be formed by epitaxially growing a semiconductor material from a surface of a second fin-type active region F2 exposed at the bottoms of the second recesses R2 and the sidewalls of the first nanosheet N1, the second nanosheet N2, and the third nanosheet N3 of each of the nanosheet stacks NSS. Referring to FIG. 7C, the semiconductor material forming the second source/drain regions SD2 may be further be grown on fin structures from an upper surface of a second fin-type active region F2 exposed by the first buried insulating film 112. A source/drain epitaxy on a fin structure may have a facetted shape as illustrated in FIG. 7C.

In example embodiments, the second source/drain regions SD2 may be formed by performing low-pressure CVD (LPCVD), selective epitaxial growth (SEG), or cyclic deposition and etching (CDE) using source materials including an elemental semiconductor precursor. The elemental semiconductor precursor may include an Si source or a Ge source. In embodiments, a PMOS transistor may be formed across the second source/drain regions SD2.

The protective insulating film 130 may be deposited on the second source/drain regions SD2. The protective insulating film 130 may be directly deposited on the second source/drain regions SD2, with no intervening layers therebetween. This may be seen in FIG. 7C. The protective insulating film 130 may include a silicon nitride film and may be selectively deposited on the top surface of each of the second source/drain regions SD2. In embodiments, the protective insulating film 130 may be formed to a thickness of about 1 nm to about 3 nm but is not limited thereto.

According to the inventive concept, source/drain regions may be formed in the second device region RX2 prior to being formed in the first device region RX1. Accordingly, a source/drain region may not be formed in the first device region RX1, as illustrated in FIG. 7A, when the source/drain regions are formed in the second device region RX2, as illustrated in FIG. 7B. FIG. 7A may show a state where the oxide film 118 may be formed on the top surface of a region, in which a source/drain region may be formed in a subsequent process.

Referring to FIG. 8A and FIG. 8B, a plurality of first recesses R1 may be formed in the first device region RX1. A plurality of first source/drain regions SD1 may be disposed in the first recesses R1. For example, the plurality of first source/drain regions SD1 may be formed to respectively fill the first recesses R1. The process of forming the first recesses R1 may be similar to the process of forming the second recesses R2, which has been described herein. The process of forming the first source/drain regions SD1 may be similar to the process of forming the second source/drain regions SD2, which has been described herein. For example, while not illustrated, a source/drain epitaxy may also be formed on fin structures in the first fin-type active region F1 exposed by the first buried insulating film 112, similar to the structure shown in FIG. 7C. A size and/or shape of the source/drain epitaxy formed on fin structures in the first fin-type active region F1 may be different than that of the source/drain epitaxy formed on fin structures in the second fin-type active region F2, but embodiments are not limited thereto. In embodiments, an NMOS transistor may be formed across the first source/drain regions SD1.

According to the inventive concept, the first source/drain regions SD1 may be formed after the second source/drain regions SD2 are formed and the protective insulating film 130 including a silicon nitride film may be deposited on the top surface of each of the second source/drain regions SD2, and open defects of the first source/drain regions SD1 may be improved. Further, an additional spacer structure may be omitted, and a recess margin corresponding to the additional spacer structure may be secured.

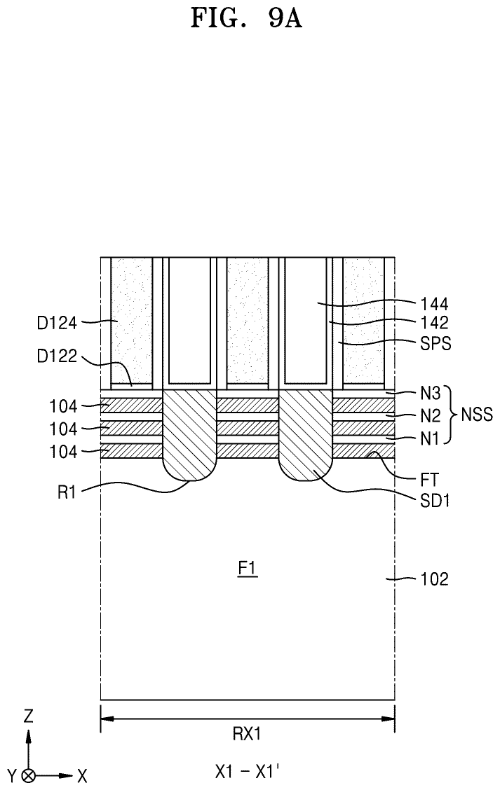

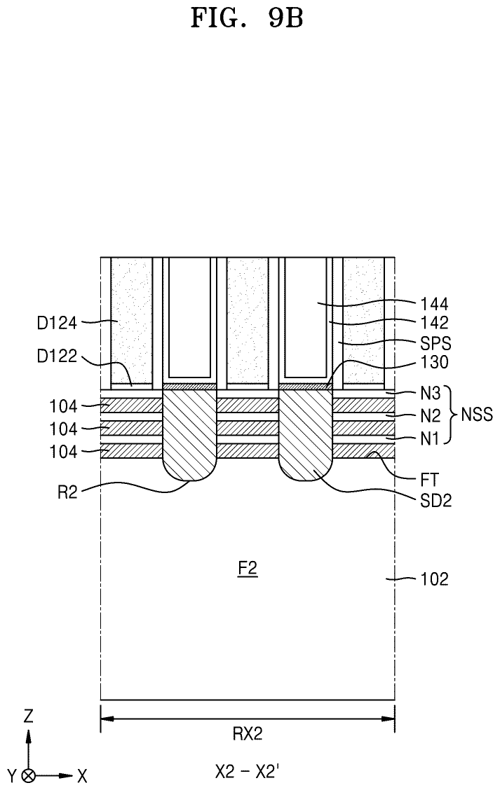

Referring to FIG. 9A and FIG. 9B, the insulating liner 142 may be formed to cover the resultant structure of FIG. 8A and FIG. 8B. The intergate insulating film 144 may be formed on the insulating liner 142. The top surface of the capping layer D126 may be exposed by planarizing the insulating liner 142 and the intergate insulating film 144. The top surface of the dummy gate layer D124 may be exposed by removing the capping layer D126. The insulating liner 142 and the intergate insulating film 144 may be partially removed such that the top surface of the intergate insulating film 144 may be substantially coplanar with the top surface of the dummy gate layer D124.

Referring to the cross-sectional view of FIG. 8A, in which the first source/drain regions SD1 have been formed, and the cross-sectional views of FIG. 7B and FIG. 7C, in which the second source/drain regions SD2 have been formed, the insulating liner 142 may directly deposited on the top surface of each of the first source/drain regions SD1 exposed without a protective insulating film (see FIG. 8A), and the height of the top surface of the insulating liner 142 after the deposition of the insulating liner 142 in FIG. 9A and FIG. 9B may be different between the first device region RX1 and the second device region RX2. For example, a vertical level of a lowermost portion of the top surface of the insulating liner 142 in the first fin-type active region F1 may be different from a vertical level of a lowermost portion of the top surface of the insulating liner 142 in the second fin-type active region F1. In another example, a height of a lowermost portion of the insulating liner 142 above the second fin-type active region F2 may be greater than a height of a lowermost portion of the insulating liner 142 above the first fin-type active region F1 according to a thickness of the protective insulating film 130. In embodiments, the difference in the height of the insulating liner 142 between the first device region RX1 and the second device region RX2 may correspond to the thickness of the protective insulating film 130. For example, different portions of the insulating liner 142 conformally disposed on the first source/drain region SD1 and the protective insulating film 130 may have different levels corresponding to the thickness of the protective insulating film 130 disposed on the second source/drain region SD2.

In an embodiment, the protective insulating film 130 may be deposited on the second source/drain regions SD2. For example, the protective insulating film 130 may be deposited on every facet of each of the second source/drain regions SD2. In an embodiment, the bottom surface of the protective insulating film 130 may be at the same vertical level as the top surface of each of the second source/drain regions SD2. In other words, the protective insulating film 130 may be directly disposed on each of the second source/drain regions SD2 without an intervening layer. In an embodiment, a topmost surface of the first buried insulating film 112 covering the second fin-type active regions F2 may have a different composition than the second source/drain regions SD2.

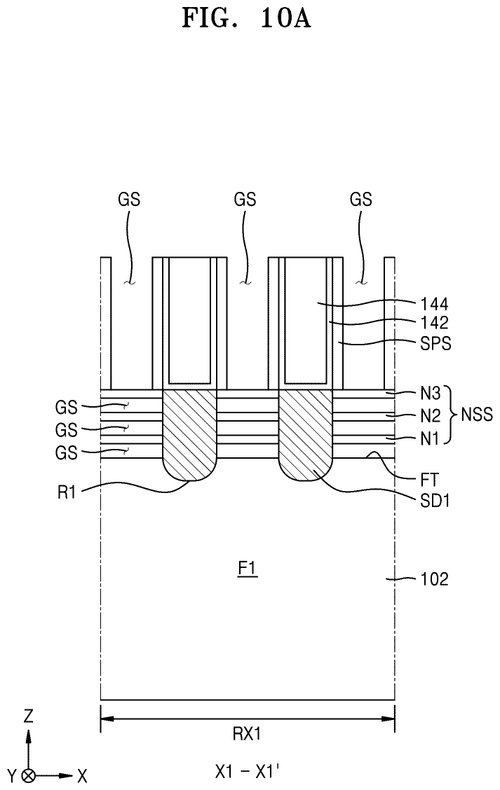

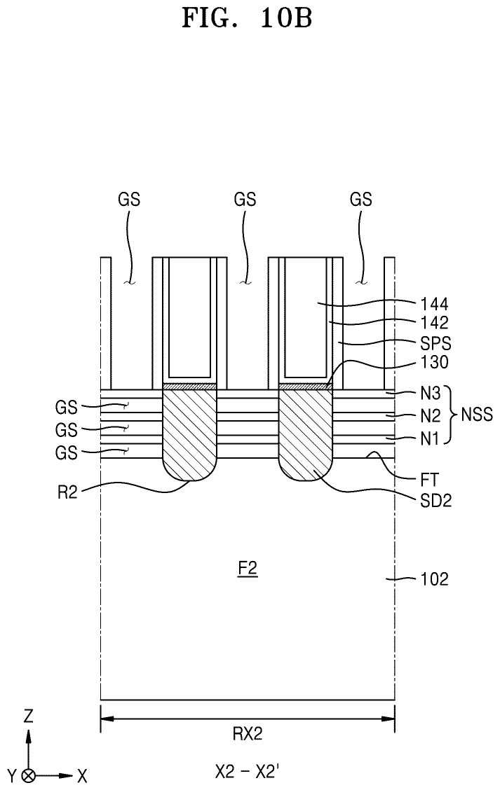

Referring to FIG. 10A and FIG. 10B, a gate space GS may be formed by removing the dummy gate layer D124 and the oxide film D122 from the resultant structure of FIG. 9A and FIG. 9B. The nanosheet stacks NSS may be exposed by the gate space GS. The sacrificial semiconductor layers 104, which may be remaining on the first and second fin-type active regions F1 and F2, may be removed through the gate space GS such that the gate space GS may extend to a space among the first nanosheet N1, the second nanosheet N2, and the third nanosheet N3 and a space between the first nanosheet N1 and the fin top FT. In embodiments, to selectively remove the sacrificial semiconductor layers 104, the difference in etch selectivity between the sacrificial semiconductor layers 104 and the first to third nanosheets N1, N2, and N3 may be used.

To selectively remove the sacrificial semiconductor layers 104, a liquid or gas etchant may be used. In embodiments, to selectively remove the sacrificial semiconductor layers 104, a CH₃COOH-based etchant, e.g., an etchant including a mixture of CH₃COOH, HNO₃, and HF or a mixture of CH₃COOH, H₂O₂, and HF, may be used, but embodiments are not limited thereto.

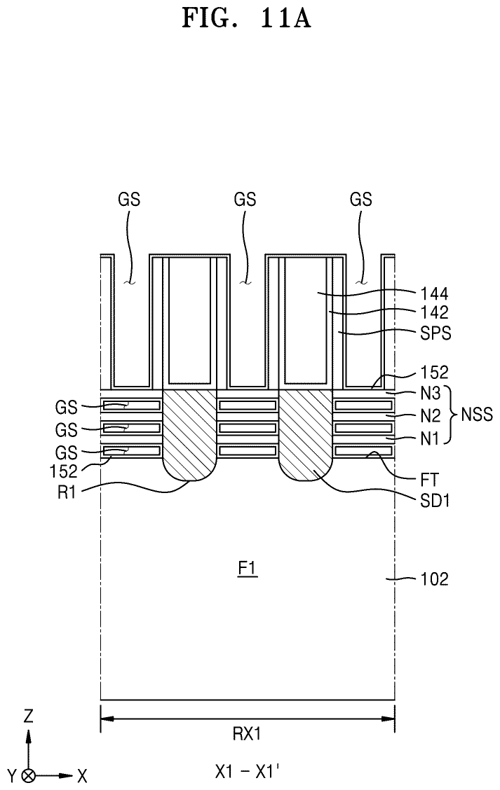

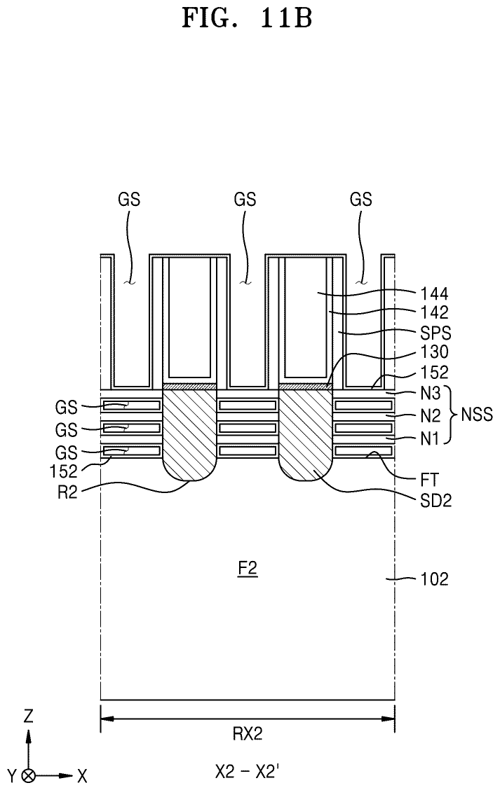

Referring to FIG. 11A and FIG. 11B, the gate dielectric film 152, which covers the exposed surface of each of the first nanosheet N1, the second nanosheet N2, the third nanosheet N3, and the first fin-type active regions F1 and the second fin-type active regions F2 in the resultant structure of FIG. 10A and FIG. 10B, may be formed. Atomic layer deposition (ALD) may be used to form the gate dielectric film 152.

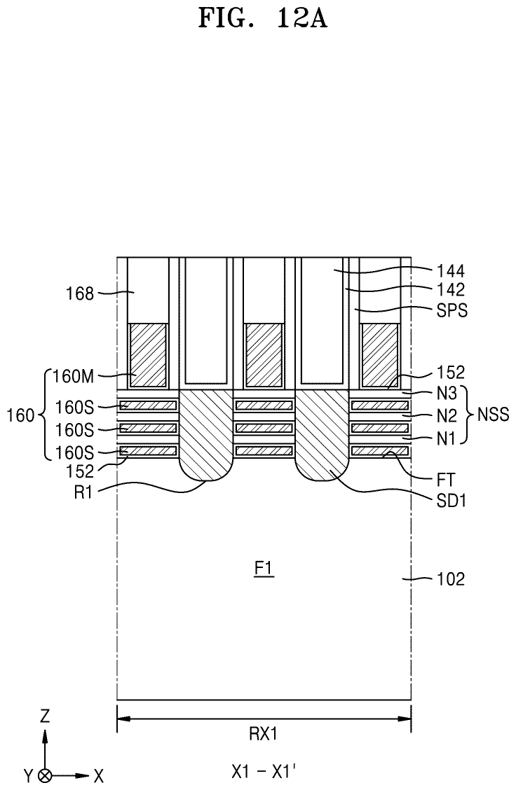

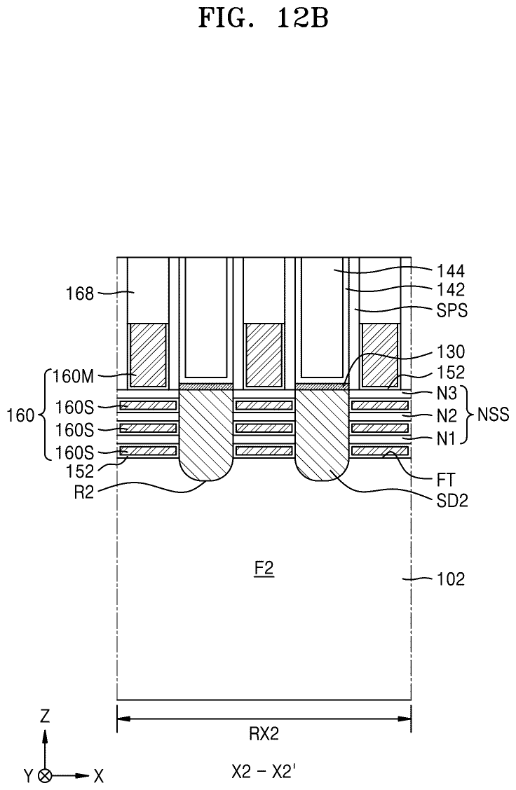

Referring to FIG. 12A and FIG. 12B, the gate line 160 may be formed on the gate dielectric film 152 to be disposed in the gate space GS (see FIG. 11A and FIG. 11B) and a capping insulating pattern 168 may be formed to cover the top surface of the gate line 160 in the gate space GS and the top surface of the gate dielectric film 152. For example, the gate line 160 may be formed on the gate dielectric film 152 to fill the gate space GS.

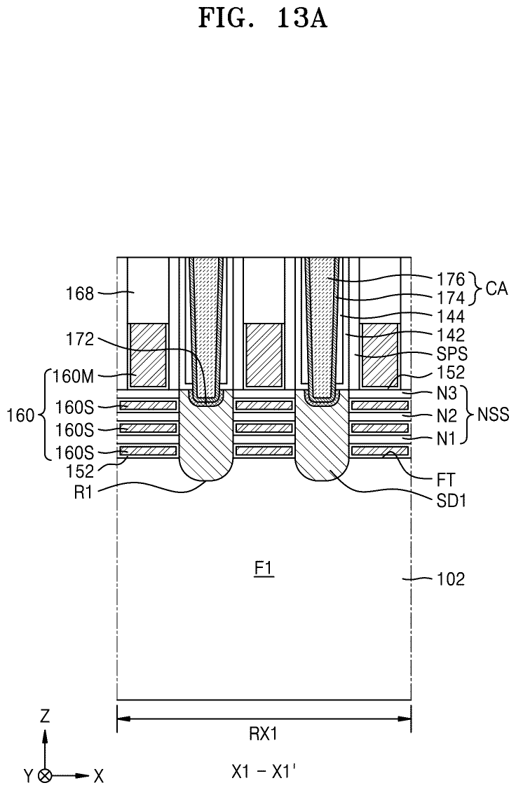

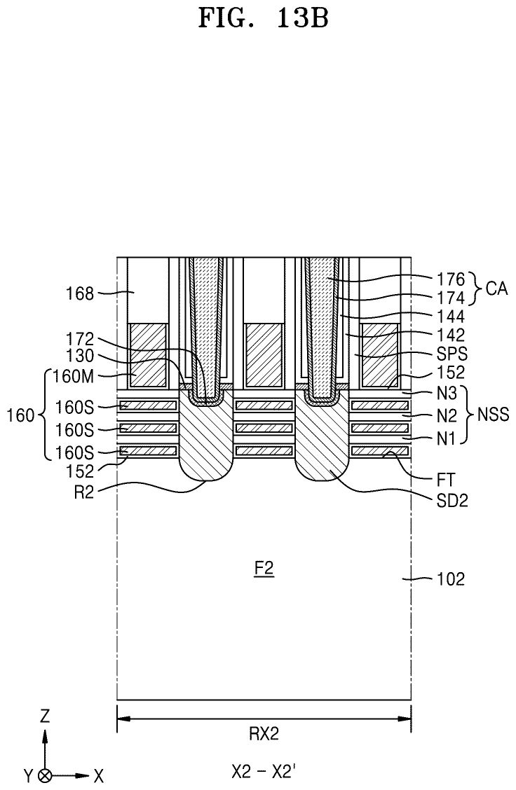

Referring to FIG. 13A and FIG. 13B, first and second source/drain contact holes may be formed to penetrate an insulating structure, which includes the insulating liner 142 and the intergate insulating film 144, and respectively expose the first and second source/drain regions SD1 and SD2 in the resultant structure of FIG. 12A and FIG. 12B. Portions of the first and second source/drain regions SD1 and SD2 may be anisotropically etched through the first and second source/drain contact holes such that the first and second source/drain contact holes may extend further toward the substrate 102. A metal silicide film 172 may be formed on the exposed portion of each of the first and second source/drain regions SD1 and SD2 at the bottoms of the first and second source/drain contact holes. In embodiments, the forming of the metal silicide film 172 may include forming a metal liner (not shown). The metal liner may conformally cover the exposed surface of each of the first and second source/drain regions SD1 and SD2. A reaction between each of the first and second source/drain regions SD1 and SD2 and metal included in the metal liner may be induced by performing a heat treatment on the metal liner. After the metal silicide film 172 is formed, the residue of the metal liner may be removed. During the process of forming the metal silicide film 172, the first and second source/drain regions SD1 and SD2 may be partially consumed. In embodiments, when the metal silicide film 172 includes a titanium silicide film, the metal liner may include a Ti film. A source/drain contact CA including a conductive barrier pattern 174 and a contact plug 176 may be formed on the metal silicide film 172.

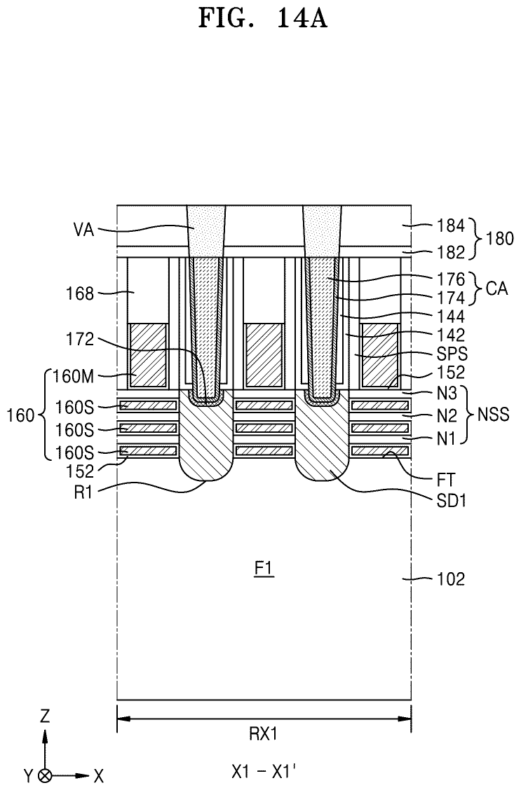

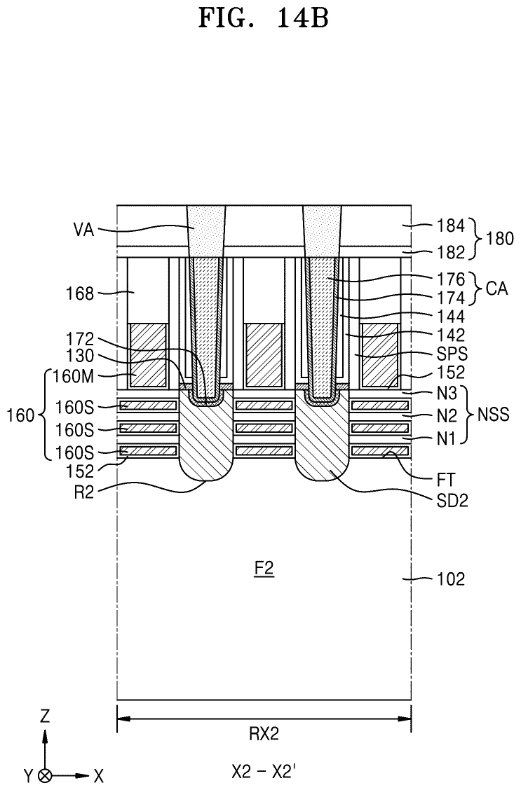

Referring to FIG. 14A and FIG. 14B, the etch stop film 182 and the interlayer insulating film 184 may be sequentially formed to cover the top surfaces of the intergate insulating film 144, a plurality of source/drain contacts CA, and a plurality of capping insulating patterns 168, thereby forming the upper insulating structure 180. A plurality of source/drain via contacts VA, which penetrate the upper insulating structure 180 in the vertical direction (the Z direction) and may be respectively connected to the source/drain contacts CA, may be formed. The gate contact CB (see FIG. 1), which penetrates the upper insulating structure 180 and a capping insulating pattern of the capping insulating patterns 168 in the vertical direction (the Z direction), and is connected to the gate line 160, may be formed. The formation order of the source/drain via contacts VA and the gate contact CB (see FIG. 1) is not particularly limited.

An upper insulating film (not shown) may be formed to cover the upper insulating structure 180 and a plurality of upper wiring layers (not shown) may be formed to penetrate the upper insulating film to be connected to the source/drain via contacts VA and the gate contact CB.

While the inventive concept has been particularly shown and described with reference to embodiments thereof, it will be understood that various changes in form and details may be made therein without departing from the spirit and scope of the following claims.

What is claimed is:

1. An integrated circuit device comprising:
a first fin-type active region and a second fin-type active region, each extending on a substrate in a first horizontal direction;
a plurality of gate lines on the first fin-type active region and second fin-type active region, the plurality of gate lines extending in a second horizontal direction that crosses the first horizontal direction;
a first source/drain region and a second source/drain region respectively in the first fin-type active region and second fin-type active region, wherein each of the first source/drain region and the second source/drain region is disposed between the plurality of gate lines;
a spacer structure disposed on the plurality of gate lines, the first source/drain region and the second source/drain region; and
a protective insulating film disposed on the second source/drain region and exposing the first source/drain region.

2. The integrated circuit device of claim 1, wherein the protective insulating film is formed on the second source/drain region to a thickness of about 1 nanometer (nm) to about 3 nm.

3. The integrated circuit device of claim 1, wherein the protective insulating film is disposed directly on the second source/drain region.

4. The integrated circuit device of claim 1, wherein the protective insulating film includes a silicon nitride film.

5. The integrated circuit device of claim 1, further comprising an insulating liner conformally covering a top surface of the first source/drain region in the first source/drain region, a top surface of the protective insulating film in the second source/drain region, and a sidewall of the spacer structure in the first source/drain region and in the second source/drain region.

6. The integrated circuit device of claim 5, wherein a vertical level of a top surface of the insulating liner above the first fin-type active region is different from a vertical level of the top surface of the insulating liner above the second fin-type active region.

7. The integrated circuit device of claim 1, wherein the protective insulating film is deposited on every facet of the second source/drain region.

8. The integrated circuit device of claim 1, further comprising an isolation film disposed in the second fin-type active region, wherein a composition of the isolation film is different from a composition of the second source/drain region.

9. The integrated circuit device of claim 1, wherein an n-channel metal-oxide semiconductor (NMOS) transistor is formed in the first source/drain region and a p-channel MOS (PMOS) transistor is formed in the second source/drain region.

10. An integrated circuit device comprising:
a substrate including a first device region, a second device region, and a device isolation region defining the first device region and the second device region;
a first fin-type active region in the first device region and a second fin-type active region in the second device region, the first fin-type active region and the second fin-type active region extending in a first horizontal direction;
a nanosheet stack disposed on each of the first fin-type active region and the second fin-type active region;
a gate line disposed above the first fin-type active region and second fin-type active region, the gate line surrounding the nanosheet stack and extending across the first second device region and the second device region and the device isolation region in a second horizontal direction that crosses the first horizontal direction;
a first source/drain region in the first fin-type active region and a second source/drain region in the second fin-type active region, the first source/drain region and the second source/drain region being adjacent to the gate line and in contact with the nanosheet stack;
a spacer structure covering a sidewall of the gate line and portions of the first source/drain region and the second source/drain region;
an insulating liner covering the spacer structure and top surfaces of the first source/drain region and the second source/drain region; and
a protective insulating film disposed on the second source/drain region and exposing the first source/drain region.

11. The integrated circuit device of claim 10, wherein a bottom surface of the protective insulating film is at a same vertical level as a top surface of the second source/drain region.

12. The integrated circuit device of claim 10, wherein the protective insulating film is formed to a thickness of about 1 nanometer (nm) to about 3 nm in a vertical direction that is perpendicular to the first horizontal direction and the second horizontal direction.

13. The integrated circuit device of claim 10, wherein the protective insulating film includes a silicon nitride film.

14. The integrated circuit device of claim 10, wherein a height of a lowermost portion of the insulating liner above the second fin-type active region is greater than a height of a lowermost portion of the insulating liner above the first fin-type active region by a thickness of the protective insulating film.

15. The integrated circuit device of claim 10, wherein the protective insulating film is deposited on every facet of the second source/drain region.

16. The integrated circuit device of claim 10, further comprising an isolation film disposed on the second fin-type active region, wherein a composition of a topmost surface of the isolation film is different from a composition of the second source/drain region.

17. The integrated circuit device of claim 10, wherein an n-channel metal-oxide semiconductor (NMOS) transistor is formed in the first source/drain region and a p-channel MOS (PMOS) transistor is formed in the second source/drain region.

18. An integrated circuit device comprising:
a first fin-type active region and a second fin-type active region;
a first source/drain region disposed in the first fin-type active region and a second source/drain region disposed in the second fin-type active region;
a plurality of nanosheet stacks each including at least one nanosheet in contact with any one of the first fin-type active region and the second fin-type active region;
a gate line disposed above the first fin-type active region and the second fin-type active region, the gate line surrounding the at least one nanosheet and extending in a direction that crosses an extension direction of the first fin-type active region and the second fin-type active region;
a plurality of spacer structures covering the gate line, the first source/drain region and the second source/drain region;
a protective insulating film disposed only on the second source/drain region among the first source/drain region and the second source/drain region; and
an insulating liner covering a top surface of the first source/drain region, a top surface of the protective insulating film, and sidewalls of the plurality of spacer structures,
wherein the protective insulating film includes a silicon nitride film, and
a difference between a height of the insulating liner above the second fin-type active region and a height of the insulating liner above the first fin-type active region corresponds to a thickness of the protective insulating film.

19. The integrated circuit device of claim 18, wherein the protective insulating film is deposited on every facet of the second source/drain region, and
a composition of a topmost surface of an isolation film disposed in the second fin-type active region is different from a composition of the second source/drain region.

20. The integrated circuit device of claim 18, wherein an n-channel metal-oxide semiconductor (NMOS) transistor is formed in the first source/drain region and a p-channel MOS (PMOS) transistor is formed in the second source/drain region.
